(19) United States
(12) Patent Application Publication
(10) Pub. No.: US 2011/0234312 A1
(43) Pub. Date: Sep. 29, 2011

(54) AMPLIFIER WITH IMPROVED STABILITY

(75) Inventors: Ashish Lachhwani, Bangalore (IN); Preetam Charan Anand Tadeparthy, Bangalore (IN); Rakesh Kumar, Ghazipur (IN)

(73) Assignee: Texas Instruments Incorporated, Dallas, TX (US)

(21) Appl. No.: 12/730,269

(22) Filed: Mar. 24, 2010

(51) Int. Cl. H03F 1/34

(52) U.S. Cl. 330/104

(57) ABSTRACT

A circuit includes an amplifier that defines a positive input terminal, a negative input terminal, a positive output terminal and a negative output terminal. The circuit also includes a first positive feedback path between the positive input terminal and the positive output terminal of the amplifier. Further, the circuit includes a second positive feedback path between the negative input terminal and the negative output terminal of the amplifier. The first positive feedback path and the second positive feedback path compensate the amplifier.

### TECHNICAL FIELD

Embodiments of the disclosure relate to an amplifier.

### BACKGROUND

An exemplary two-stage operational amplifier 100, hereinafter referred to as the amplifier 100, is illustrated in FIG. 1 (Prior Art). The amplifier 100 includes a first differential amplifier 105, hereinafter referred to as the amplifier 105, and a second differential amplifier 110, hereinafter referred to as the amplifier 110. A first resistive-capacitive (RC) circuit 115 acts as a load for the first differential amplifier 105 and a second RC load 120 acts as a load for the second differential amplifier 110. To achieve desired stability and reliable operation from the amplifier 100 across process, voltage and temperature (PVT) variations, loading, and feedback conditions, the amplifier 100 needs to be compensated.

An existing technique for compensating the amplifier 100 is Miller compensation. A first capacitor is coupled between a negative output terminal 125 and a positive input terminal 130, and a second capacitor is coupled between a positive output terminal 135 and a negative input terminal 140 of the amplifier 110. However, the first capacitor and the second capacitor result in introduction of a zero in a right half plane of a frequency response of the amplifier 100, and hence limit phase. Further, the zero in the frequency response leads to instability.

Another existing technique for compensating the amplifier 100 is feed-forward compensation. An amplifier is coupled between input terminals 145 and output terminals 150 of the amplifier 100. The amplifier in the feed-forward path results in high power and area requirement. Moreover, having the amplifier in feed forward path necessitates stringent noise requirement.

### SUMMARY

An example of a circuit includes an amplifier that defines a positive input terminal, a negative input terminal, a positive output terminal and a negative output terminal. The circuit also includes a first positive feedback path between the positive input terminal and the positive output terminal of the amplifier. Further, the circuit includes a second positive feedback path between the negative input terminal and the negative output terminal of the amplifier. The first positive feedback path and the second positive feedback path compensate the amplifier.

An example of an amplifier includes a first stage amplifier including a first positive input terminal, a first negative input terminal, a first positive output terminal and a first negative output terminal. The amplifier also includes a first resistive-capacitive load coupled to the first positive output terminal and the first negative output terminal. Further, the amplifier includes a second stage amplifier that includes a second positive input terminal, a second negative input terminal, a second positive output terminal and a second negative output terminal. The first positive output terminal is coupled to the second negative input terminal and the first negative output terminal is coupled to the second positive output terminal. Further, the amplifier also includes a first capacitor coupled between the second positive input terminal and the second positive output terminal. The amplifier also includes a second capacitor coupled between the second negative input terminal and the second negative output terminal. Furthermore, the amplifier also includes a second resistive-capacitive load coupled to the second negative input terminal and the second negative output terminal. The first capacitor and the second capacitor compensate the amplifier.

Another example of an amplifier includes a first amplifier that defines a first positive input terminal, a first negative input terminal, and a first output terminal. The amplifier also includes a second amplifier, coupled to the first output terminal, that defines a second positive input terminal, a second negative input terminal, and a second output terminal. Further, the amplifier includes a capacitor coupled between the second output terminal, and one of the second positive input terminal and the second negative input terminal. The capacitor compensates the amplifier.

### BRIEF DESCRIPTION OF THE VIEWS OF DRAWINGS

In the accompanying figures, similar reference numerals may refer to identical or functionally similar elements. These reference numerals are used in the detailed description to illustrate various embodiments and to explain various aspects and advantages of the disclosure.

FIG. 1 illustrates a two stage operational amplifier for differential signaling in accordance with prior art;

FIG. 2 illustrates an amplifier in accordance with one embodiment;

FIG. 3 illustrates an amplifier in accordance with another embodiment;

FIG. 4 illustrates phase margin obtained in accordance with one embodiment; and

FIG. 5 illustrates gain obtained in accordance with one embodiment.

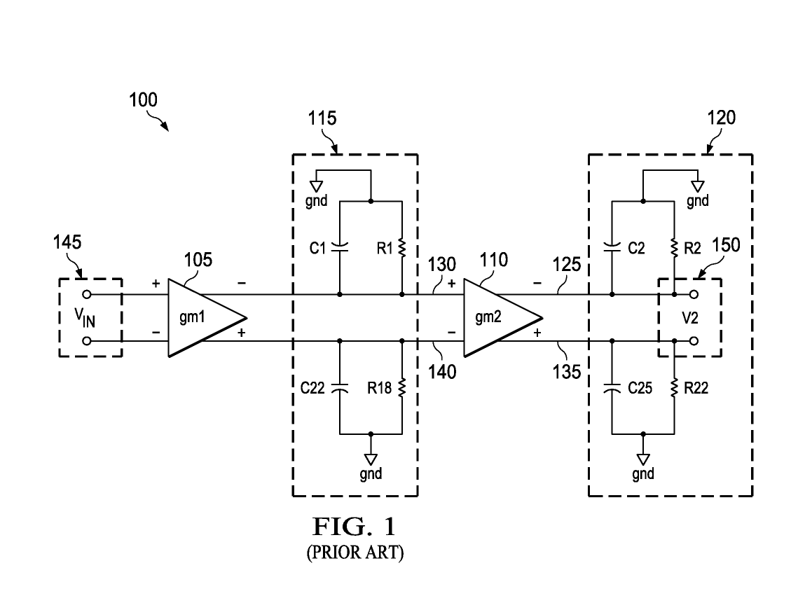

### DETAILED DESCRIPTION OF THE EMBODIMENTS

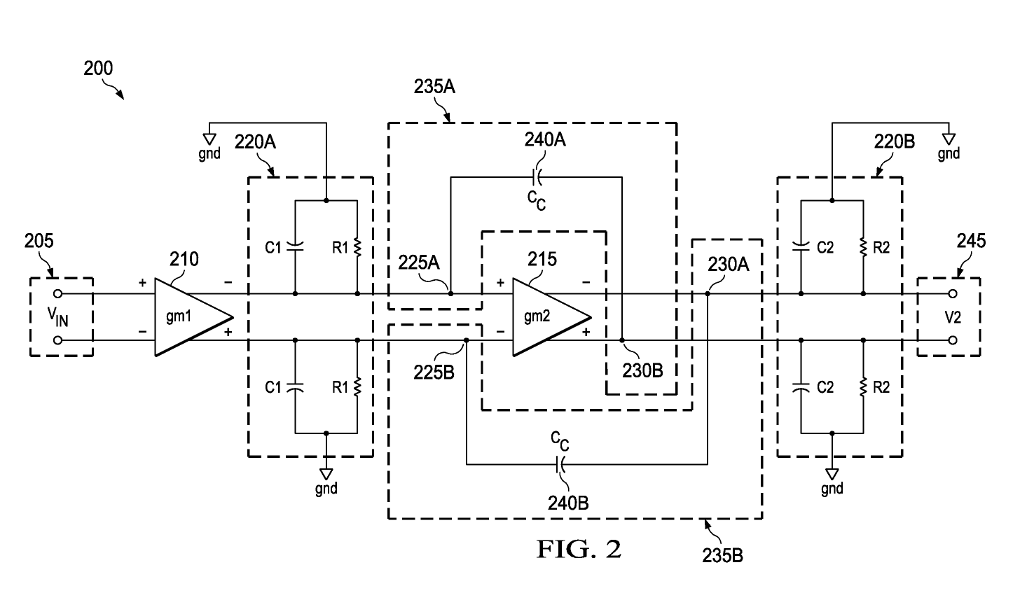

FIG. 2 illustrates a multistage amplifier, for example an amplifier 200. The amplifier 200 includes an input (first) stage amplifier 210, hereinafter referred to as the amplifier 210, and an output (second) stage amplifier 215, hereinafter referred to as the amplifier 215, in a series connection.

The amplifier 210 is coupled to input terminals 205 of the amplifier 200. Output terminals of the amplifier 210 are coupled to a load, for example a resistive-capacitive (RC) load 220A. The RC load 220A (first RC load) can include one or more RC loads. One terminal of the RC load 220A is coupled to a ground supply (GND). The amplifier 210 defines a first positive input terminal and a first negative input terminal, collectively referred to as the input terminals 205, and a first positive output terminal and a first negative output terminal, collectively referred to as the output terminals.

A positive terminal can be defined as a non-inverting terminal, and a negative terminal can be defined as an inverting terminal.

Input terminals of the amplifier 215 are coupled to the output terminals of the amplifier 210. A second positive input terminal 225A, hereinafter referred to as the terminal 225A, of the amplifier 215 is coupled to the first negative output terminal of the amplifier 210. A second negative input terminal 225B, hereinafter referred to as the terminal 225B, of the amplifier 215 is coupled to the first positive output terminal of the amplifier 210. Output terminals of the amplifier 215 are coupled to the input terminals of the amplifier 215 in a positive feedback through coupling capacitors. A capacitor 240A is coupled between a second positive output terminal 230B, hereinafter referred to as the terminal 230B, and the terminal 225A. Similarly, a capacitor 240B is coupled between a second negative output terminal 230A, hereinafter known as the terminal 230A, of the amplifier 215 and the terminal 225B of the amplifier 215. The capacitor 240A defines a first positive feedback path 235A between the terminal 230B and the terminal 225A. Similarly, the capacitor 240B defines a second positive feedback path 235B between the terminal 230A and the terminal 225B. The terminal 230A and the terminal 230B are coupled to a load, for example a RC load 220B. The RC load 220B (second RC load) is coupled to the ground supply (GND) and can include one or more RC loads. The terminal 230A and the terminal 230B are also coupled to output terminals 245 of the amplifier 200.

The RC load 220A and the RC load 220B can be identical, for example having similar resistance and capacitance, or can be different. Each RC load includes a resistor and a capacitor in a parallel connection. The RC load 220A includes resistors having a resistance R1 and capacitors having a capacitance C1. The RC load 220B includes resistors having a resistance R2 and capacitors having a capacitance C2.

In some embodiments, the capacitor 240A and the capacitor 240B are identical having similar capacitances, and can be metal oxide semiconductor (MOS) type capacitors. The MOS type capacitors have high density, and low process and temperature variations which helps in improving stability of the amplifier 200 across the process and temperature variations. Examples of the capacitor 240A and the capacitor 240B can include, but are not limited to one of ceramic capacitors, air gap capacitors, vacuum capacitors, dielectric capacitors and film capacitors. The capacitor 240A and the capacitor 240B have a capacitance C_{C}.

The amplifier 210 and the amplifier 215 are differential amplifiers having transconductance “gm1” and “gm2” respectively. The amplifier 210 can also be referred to as a preceding amplifier providing output to the amplifier 215. In some embodiments, gm1 is greater than gm2.

In some embodiments, the amplifier 210 can be a combination of one or more amplifiers in the series connection.

In some embodiments, the amplifier 200 can be a single stage amplifier including the amplifier 215 and the positive feedback paths.

A differential input signal (Vin) is received at the input terminals 205. The amplifier 210 amplifies the differential input signal to provide an amplified differential signal. The amplifier 215 amplifies the amplified differential signal to provide a differential output signal (V2).

The RC load 220A and the RC load 220B result in introduction of two poles, for example a first pole and a second pole, in a frequency response of the amplifier 200. The frequency response for a system can be defined as a measure of an output of the system in a frequency domain in response to an input. The two poles correspond to two different frequencies.

A standard transfer function of the system is represented as

$$[ H ( s ) ] = \frac{N ( s )}{D ( s )} = [ K * \frac{( s - z 1 ) * ( s - z 2 ) * … * ( s - {z}_{n} )}{( s - p 1 ) * ( s - p 2 ) * … * ( s - {p}_{n} )} ] \qquad ( 1 )$$

where N(s) is numerator and D(s) is denominator, and K is a gain factor.

The transfer function can be defined as a mathematical representation, in terms of frequency, of a relation between the input and the output of the system. Further, the transfer function can be defined as linear mapping of Laplace transform of the input to the output. Poles for equation (1) can be determined by equating the denominator to zero. The poles can be determined as p1, p2 and so on. Similarly, zeros for equation (1) can be determined by equating the numerator to zero. The zeros can be determined as z1, z2 and so on.

In existing miller compensation technique for a two pole amplifier, a feedback capacitor connects an output terminal to an input terminal of the two pole amplifier. The feedback capacitor defines a negative feedback path for the two pole amplifier. Since a capacitor is a bi-directional device, the feedback capacitor results in a feedback path as well as a feed forward path. In the feedback path, product of gain and feedback capacitance results in splitting of poles by moving a first pole to a high frequency and moving a second pole to a low frequency. Hence, the splitting of the poles results in a wide bandwidth in the frequency response of the two pole amplifier. The wide bandwidth signifies a stable system. However, in the feed forward path, the feedback capacitor results in introduction of a right half plane zero (RHPZ) in the frequency response of the two pole amplifier. The introduction of the RHPZ limits the maximum achievable bandwidth by restricting the bandwidth to the frequency where the RHPZ is located on the frequency response.

In the amplifier 200, the capacitor 240A and the capacitor 240B are the feedback capacitors for the amplifier 215. The capacitor 240A and the capacitor 240B compensate the amplifier 200 to achieve desired stability and reliable operation from the amplifier 200 across process, voltage and temperature (PVT) variations, loading, and feedback conditions. The capacitor 240A and the capacitor 240B are bi-directional devices. The capacitor 240A defines the first positive feedback path 235A from the terminal 230B to the terminal 225A. The capacitor 240B defines the second positive feedback path 235B from the terminal 230A to the terminal 225B.

The capacitor 240A enables flow of a first feedback current from the terminal 230B to the terminal 225A, and is used to sense the voltage at the terminal 230B to provide the first feedback current. The capacitor 240A by defining the first positive feedback path from the terminal 230B to the terminal 225A enables generation of the first feedback current. The first feedback current can be equal to V*wC_{C}, where V is the voltage across the capacitor 240A. Similarly, the capacitor 240B enables flow of a second feedback current from the terminal 230A to the terminal 225B, and is used to sense the voltage at the terminal 230A to provide the second feedback current. The capacitor 240B by defining the second positive feedback path from the terminal 230A to the terminal 225B enables generation of the second feedback current.

The voltages charged across the capacitor 240A and the capacitor 240B is fed in combination with the amplified differential signal at the terminal 225A and the terminal 225B respectively.

The capacitor 240A and the capacitor 240B split the two poles created due to the RC load 220A and the RC load 220B by moving the first pole to a low frequency and the second pole to a high frequency in the frequency response of the amplifier 200 resulting in high gain-bandwidth product and thus compensating the amplifier 200. The poles can be determined using equation (2) by comparing denominator to zero. The splitting is performed due to the product (gm2*C_{C}) of gain and feedback capacitance. The splitting is also achieved due to the sensing of the voltages at the terminal 230B and at the terminal 230A, and by providing the feedback currents by the capacitor 240A and the capacitor 240B respectively.

Further, the capacitor 240A provides a first positive feed forward path from the terminal 225A to the terminal 230B in addition to the first positive feedback 235A path from the terminal 230B to the terminal 225A. Similarly, the capacitor 240B provides a second positive feed forward path from the terminal 225B to the terminal 230A in addition to the second positive feedback path 235B from the terminal 230A to the terminal 225B. The first positive feed forward path and the second positive feed forward path result in a left half plane zero (LHPZ), in the frequency response of the amplifier 200. Hence, stability and phase margin of the amplifier 200 is improved. The left half plane zero can be obtained from equation (2) by equating numberator to zero. The left half plane zero can be determined as gm2/C_{C}.

The first positive feedback path 235A and the second positive feedback path 235B result in compensation of the amplifier 200 due to the capacitor 240A and the capacitor 240B.

Gain of the amplifier 200 is determined as a ratio of magnitudes of the differential output signal and of the differential input signal.

$$\frac{V 2}{Vin} = \frac{[ - gm 1 * ( s * {C}_{c} - gm 2 ) ]}{[ \begin{matrix}s * {C}_{c} * ( s * {C}_{c} + gm 2 ) - \\ ( gm 1 + s * ( C 1 + {C}_{c} ) ) * ( gm 1 + s * ( C 1 + {C}_{c} ) )\end{matrix} ]} \qquad ( 2 )$$

where gm1 is the transconductance of the amplifier 210, gm2 is the transconductance of the amplifier 215, s represents complex frequency domain, C1 is the capacitance of the RC load 220A and C_{C} is capacitance of the capacitor 240A and the capacitor 240B.

Using equation (2), the numerator in [1+(V2/Vin)] denotes characteristic equation of a feedback system of the amplifier 200. The feedback system includes the positive feedback paths.

The poles and zeros of the amplifier 200 can be determined using equation (1) and the equation (2). The zeroes can be obtained by equating numerator of equation (2) to zero. The frequency response has numerator and denominator similar to that shown in equation (2).

A stable two pole system can be represented as

$$H ( s ) = \frac{1}{\frac{{s}^{2}}{{ω}_{0}^{2}} + \frac{s}{{ω}_{0} Q} + 1} \qquad ( 3 )$$

The first degree s-term coefficients of equation 1+V2/Vin is compared with the s-term coefficients of equation (3) to determine the s-term coefficients of the amplifier 200 as [−gm2*C_{C}−gm2*(C1−C_{C})−gm1*(C2−C_{C})−gm1*C_{C}].

Quality factor (Q) can be defined as

$$Q = \frac{R 1 * R 2 \sqrt{gm 1 * gm 2 * C 1 * C 2}}{R 1 * C 1 + R 2 * C 2 + [ R 1 * R 2 * {C}_{c} * ( gm 1 - gm 2 ) ]} \qquad ( 4 )$$

where R1 is the resistance of the RC load 220A and R2 is the resistance of the RC load 220B, gm1 is the transconductance of the amplifier 210, gm2 is the transconductance of the amplifier 215, C1 is the capacitance of the RC load 220A, C2 is the capacitance of the RC load 220B and C_{C} is the capacitance of the capacitor 240A and the capacitor 240B.

Quality factor indicates stability of the amplifier 200. Lower the quality factor higher is the stability. The term (gm1−gm2) in denominator of the equation (4) indicates that the capacitance C_{C} results in a lower quality (Q) factor for the condition gm1>gm2. One or more parameters, for example power consumption in micro amperes, area utilized in micro square meters, unity gain bandwidth in mega hertz (MHz), phase margin achieved in terms of degrees, gain achieved in decibels (dB), total harmonic distortion (THD) at 0.6 Vₚ₋ₚ in decibels relative to carrier (dBc), input referred noise at 1 MHz in nano volts per square root of hertz (nV/sqrt (Hz)) are also indicative of the reliability of the amplifier 200. The gain bandwidth product (GBW or GB) of the amplifier 215 can be defined as a product of open-loop gain and bandwidth of the amplifier 215. Table 1 illustrates value of the parameters obtained with the load including a resistance of 10 kilo ohms and a capacitance of 2 pico farads. The phase margin and the gain are high, and hence improved.

TABLE 1

| Parameters | Values | Units |
|---|---|---|
| Power | 684.4 | μA |
| Area | 12960 | μm² |
| Unity Gain-Bandwidth | 91 | MHz |
| Phase Margin | 58.5 | Degrees |
| Gain | 33 | dB |
| THD at 0.6 Vₚ₋ₚ | 42.1 | dBc |
| 5 MHz output(β = 0.5) | | |
| Input referred noise at 5 MHz | 2.72 | nV/sqrt (Hz) |
| Variation of Phase Margin | +/−4 | Degrees |
| over PVT | | |

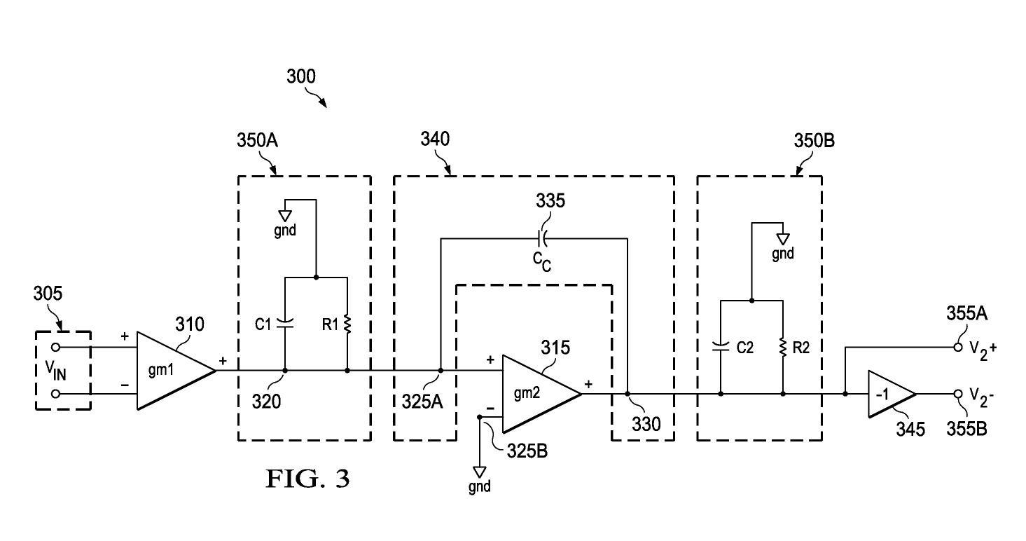

Referring to FIG. 3 now, an amplifier 300 includes a first amplifier 310 (first stage) that defines a first positive input terminal and a first negative input terminal, collectively referred to as the input terminals 305, and a first output terminal 320, hereinafter known as the terminal 320. The terminal 320 can be a positive output terminal.

The amplifier 300 also includes a second amplifier 315 (second stage) coupled to the first amplifier 310, for example through the terminal 320. The second amplifier 315 defines a second positive input terminal 325A, hereinafter referred to as the terminal 325A, a second negative input terminal 325B, hereinafter referred to as the terminal 325B, and a second output terminal 330, hereinafter known as the terminal 330. The terminal 330 can be a positive output terminal. The terminal 325A is coupled to the terminal 320. The terminal 325B is coupled to a ground supply. The terminal 330 is coupled to the terminal 325A through a capacitor 335. The capacitor 335 defines a positive feedback path 340 between the terminal 330 and the terminal 325A. The terminal 330 is further coupled to one terminal of an inverter 345. The capacitor 335 splits poles, in a frequency response of the amplifier 300 and result in high gain-bandwidth product. Further, the positive feedback path 340 results in a zero in the left hand plane of the frequency response, and hence stability and phase margin of the amplifier 300 is improved.

In some embodiments, the terminal 320 and the terminal 330 can be negative output terminals. The terminal 325A can also be a negative terminal and the terminal 325B can be a positive terminal.

A load, for example a resistive-capacitive (RC) circuit 350A is coupled to the terminal 320 of the first amplifier 310. Another resistive-capacitive (RC) circuit 350B is coupled to the terminal 330 of the first amplifier 315. The RC load 350A and the RC load 350B are coupled to the ground supply (GND).

The first amplifier 310 and the second amplifier 315 are non-differential amplifiers having transconductance “gm1” and “gm2” respectively. The first amplifier 310 can also be referred to as a preceding amplifier providing output to the second amplifier 315. In some embodiments, gm1 is greater than gm2. The inverter 345 can also be an operational amplifier.

The amplifier 310 receives an input signal (Vin) at the input terminals 305. The amplifier 310 amplifies the input signal and provides an amplified signal at the terminal 320. The amplified signal is further amplified by the amplifier 315 to generate an output signal at a terminal 355A (V2+). The output signal generated at the terminal 355A can be inverted by the inverter 345 to provide an inverted signal (V2−) at a third output terminal 355B. The terminal 355A and the third output terminal 355B have opposite polarity. The output signal (V2+) and the inverted output signal (V2−) can be represented as a differential output signal (V2).

The RC load 350A and the RC load 350B result in introduction of two poles, for example a first pole and a second pole, in a frequency response of the amplifier 300. The two poles correspond to two different frequencies.

A voltage across the capacitor 335 is fed in combination with the amplified signal at the terminal 325A. The capacitor 335 has a capacitance C_{C}. In other words, the capacitor 335 senses voltage at the terminal 330 and provides the positive feedback path 340 for a feedback current. The feedback current given by V*w C_{C}, where V is the voltage across the capacitor 335 is fed at the terminal 325A.

The capacitor 335 split the two poles by moving the first pole to a low frequency and the second pole to a high frequency, in a frequency response of the amplifier 300 resulting in high gain-bandwidth product and thus compensating the amplifier 300. The splitting is performed due to the product (gm2*C_{C}). The splitting is also achieved due to sensing of the voltage at the terminal 330 and providing the feedback current provided by the capacitor 335. The sensing enables splitting of the poles.

Further, the capacitor 335 provides a feed forward path from the terminal 325A to the terminal 330 in addition to the positive feedback path 340 from the terminal 330 to the terminal 325A. The feed forward path result in a left half plane zero (LHPZ), in the frequency response of the amplifier 300. Hence, stability and phase margin of the amplifier 300 is improved.

Gain of the amplifier 300 is determined as a ratio of magnitudes of the differential output signal and of the differential input signal.

$$\frac{V 2}{Vin} = \frac{[ - gm 1 * ( s * {C}_{c} - gm 2 ) ]}{[ \begin{matrix}s * {C}_{c} * ( s * {C}_{c} + gm 2 ) - \\ ( gm 1 + s * ( C 1 + {C}_{c} ) ) * ( gm 1 + s * ( C 1 + {C}_{c} ) )\end{matrix} ]} \qquad ( 5 )$$

where gm1 is the transconductance of the amplifier 310, gm2 is the transconductance of the amplifier 315, s represents complex frequency domain, C1 is the capacitance of the RC load 350A and C_{C} is capacitance of the capacitor 335.

Using equation (5), the numerator in [1+(V2/Vin)] denotes characteristic equation of a feedback system of the amplifier 300. The feedback system includes the positive feedback paths.

The poles and zeros of the amplifier 200 are determined by comparing equation (1) and the equation (5).

The first degree s-term coefficients of equation 1+V2/Vin is compared with the s-term coefficients of equation (3) to determine the s-term coefficients of the amplifier 300 as [−gm2*C_{C}−gm2*(C1−C_{C})−gm1*(C2−C_{C})−gm1*C_{C}].

Quality factor (Q) can be defined as

$$Q = \frac{R 1 * R 2 \sqrt{gm 1 * gm 2 * C 1 * C 2}}{R 1 * C 1 + R 2 * C 2 + [ R 1 * R 2 * {C}_{c} * ( gm 1 - gm 2 ) ]} \qquad ( 6 )$$

where R1 is the resistance of the RC load 350A and R2 is the resistance of the RC load 350B, gm1 is the transconductance of the amplifier 310, gm2 is the transconductance of the amplifier 315, C1 is the capacitance of the RC load 350A, C2 is the capacitance of the RC load 350B and C_{C} is the capacitance of the capacitor 335.

Quality factor indicates stability of the amplifier 200. Lower the quality factor higher is the stability. The term (gm1−gm2) in denominator of the equation (6) indicates that the capacitance C_{C} results in a lower quality (Q) factor for the condition gm1>gm2.

The positive feedback path 340 results in high phase margin, high gain and stability. The capacitor 335 compensates the amplifier 300 to achieve desired stability and reliable operation from the amplifier 300 across process, voltage and temperature (PVT) variations, loading, and feedback conditions. The gain bandwidth product (GBW or GB) of the amplifier 315 can be defined as a product of open-loop gain and bandwidth of the amplifier 315.

It is noted that other combinations of the first stage amplifier and the second stage amplifier can also be used. In one example, the first stage amplifier can be a differential amplifier and the second stage amplifier can be a non-differential amplifier. In another example, the first stage amplifier can be a non-differential amplifier and the second stage amplifier can be a differential amplifier.

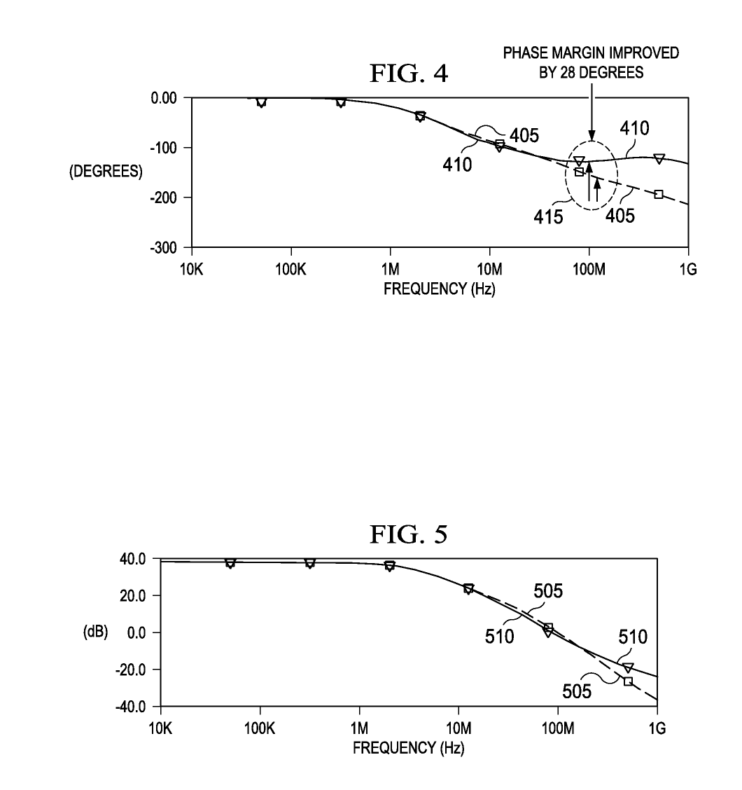

FIG. 4 illustrates phase margin obtained for the amplifier 200 in accordance with one embodiment. The conditions include gm1=3.2 mS, gm2=400 mS, R1=20 kilo ohms, C1=5 pico farads, R2=15 kilo ohms, C2=2 pico farads and C_{C}=200 femto farads.

Y-axis represents the phase margin in degrees and X-axis represents frequency in hertz. A waveform 405 corresponds to the phase margin obtained in accordance with miller compensation (prior art). A waveform 410 corresponds to the phase margin obtained in accordance with the amplifier 200. The phase margin improves by around 28 degrees as illustrated in a section 415. The waveform 410 is flat around 1 Giga hertz and hence provides robustness to movement of parasitic poles introduced due to the RC loads.

FIG. 5 illustrates gain obtained for the amplifier 200 in accordance with one embodiment. The conditions include gm1=3.2 milliSiemens (mS), gm2=400 mS, R1=20 kilo ohms, C1=5 pico farads, R2=15 kilo ohms, C2=2 pico farads and C_{C}=200 femto farads.

Y-axis represents the gain in decibels and X-axis represents frequency in hertz. A waveform 510 corresponds to the gain obtained in accordance with miller compensation (prior art). A waveform 505 corresponds to the gain obtained in accordance with the amplifier 200. The gain obtained for the amplifier 200 remains same as the gain obtained by the miller compensation (prior art) with an improvement in phase margin by around 28 degrees.

In the foregoing discussion, the term “coupled” refers to either a direct electrical connection between the devices connected or an indirect connection through one or more passive or active intermediary devices. The term “circuit” means at least either a single component or a multiplicity of components, that are connected together to provide a desired function. The term “signal” means at least one current, voltage, charge, data, or other signal.

The foregoing description sets forth numerous specific details to convey a thorough understanding of embodiments of the disclosure. However, it will be apparent to one skilled in the art that embodiments of the disclosure may be practiced without these specific details. Some well-known features are not described in detail in order to avoid obscuring the disclosure. Other variations and embodiments are possible in light of above teachings, and it is thus intended that the scope of disclosure not be limited by this Detailed Description, but only by the Claims.

What is claimed is:

1. A circuit comprising:
an amplifier that defines a positive input terminal, a negative input terminal, a positive output terminal and a negative output terminal;
a first positive feedback path, between the positive input terminal and the positive output terminal of the amplifier, that compensates the circuit; and
a second positive feedback path, between the negative input terminal and the negative output terminal of the amplifier, that compensates the circuit.

2. The circuit as claimed in claim 1, wherein
the first positive feedback path comprises a first capacitor, and
the second positive feedback path comprises a second capacitor.

3. The circuit as claimed in claim 2, wherein the first capacitor senses voltage at the positive output terminal of the amplifier and provides a first feedback current based on the voltage.

4. The circuit as claimed in claim 2, wherein the second capacitor senses voltage at the negative output terminal of the amplifier and provides a second feedback current based on the voltage.

5. The amplifier as claimed in claim 2, wherein the first capacitor and the second capacitor split poles and introduce a left half plane zero in a frequency response of the circuit, thereby compensating the circuit and preventing reduction in a bandwidth of the circuit, the left half plane zero being gm2/C_{C} that is determined by equating numerator in the frequency response
$$\frac{V 2}{Vin} = \frac{[ - gm 1 * ( s * {C}_{c} - gm 2 ) ]}{[ \begin{matrix}s * {C}_{c} * ( s * {C}_{c} + gm 2 ) - \\ ( gm 1 + s * ( C 1 + {C}_{c} ) ) * ( gm 1 + s * ( C 1 + {C}_{c} ) )\end{matrix} ]}$$
to zero, where C_{C} is capacitance of the first capacitor and the second capacitor.

6. The circuit as claimed in claim 2, wherein the first capacitor and the second capacitor are metal oxide semiconductor type capacitors.

7. The circuit as claimed in claim 1, wherein the amplifier is a differential amplifier.

8. The circuit as claimed in claim 1, wherein the circuit is a multistage amplifier and the amplifier is an output stage amplifier of the multistage amplifier.

9. The circuit as claimed in claim 1, wherein the circuit is a multistage amplifier and the amplifier has a transconductance lesser than that of a preceding amplifier, the preceding amplifier providing an output to the amplifier.

10. The circuit as claimed in claim 1, wherein the amplifier is coupled to a resistive-capacitive load.

11. An amplifier comprising:
a first stage amplifier comprising a first positive input terminal, a first negative input terminal, a first positive output terminal and a first negative output terminal;
a first resistive-capacitive load coupled to the first positive output terminal and the first negative output terminal;
a second stage amplifier comprising a second positive input terminal, a second negative input terminal, a second positive output terminal and a second negative output terminal, the first positive output terminal coupled to the second negative input terminal and the first negative output terminal coupled to the second positive output terminal;
a first capacitor, coupled between the second positive input terminal and the second positive output terminal, that compensates the amplifier;
a second capacitor coupled between the second negative input terminal and the second negative output terminal that compensates the amplifier; and
a second resistive-capacitive load coupled to the second negative input terminal and the second negative output terminal.

12. The amplifier as claimed in claim 11, wherein the second stage amplifier has transconductance lesser than that of the first stage amplifier.

13. The amplifier as claimed in claim 11, wherein the first capacitor and the second capacitor split poles and introduce a left half plane zero in a frequency response of the amplifier, thereby compensating the amplifier and preventing reduction in a bandwidth of the amplifier, the left half plane zero being gm2/C_{C} that is determined by equating numerator in the frequency response
$$\frac{V 2}{Vin} = \frac{[ - gm 1 * ( s * {C}_{c} - gm 2 ) ]}{[ \begin{matrix}s * {C}_{c} * ( s * {C}_{c} + gm 2 ) - \\ ( gm 1 + s * ( C 1 + {C}_{c} ) ) * ( gm 1 + s * ( C 1 + {C}_{c} ) )\end{matrix} ]}$$
to zero, where C_{C} is capacitance of the first capacitor and the second capacitor.

14. An amplifier comprising:
a first amplifier that defines a first positive input terminal, a first negative input terminal, and a first output terminal;
a second amplifier, coupled to the first output terminal, that defines a second positive input terminal, a second negative input terminal, and a second output terminal; and
a capacitor coupled between the second output terminal, and one of the second positive input terminal and the second negative input terminal, the capacitor compensating the second amplifier.

15. The amplifier as claimed in claim 14, wherein the capacitor split poles and introduce a left half plane zero, in a frequency response, created by the amplifier, thereby compensating the amplifier and preventing reduction in a bandwidth of the amplifier.

16. The amplifier as claimed in claim 14, wherein the first output terminal is one of positive output terminal and negative output terminal.

17. The amplifier as claimed in claim 14, wherein the second output terminal is one of positive output terminal and negative output terminal.

18. The amplifier as claimed in claim 14 and further comprising:
an inverter, coupled to the second amplifier, that defines a third output terminal.

19. The amplifier as claimed in claim 18 and further comprising:
a first resistive-capacitive load coupled to the first output terminal; and
a second resistive-capacitive load coupled to the second output terminal.

20. The amplifier as claimed in claim 14, wherein the second amplifier has transconductance lesser than that of the first amplifier.
